(19) United States
(12) Patent Application Publication
(10) Pub. No.: US 2004/0234777 A1
(43) Pub. Date: Nov. 25, 2004

(54) Method for electroless plating without precious metal sensitization

(76) Inventor: John Grunwald, Ramat Gan (IL)

Correspondence Address: Edward Langer, c/o Shiboleth, Yisraeli, Roberts, Zisman & Co., 60th Floor, 350 Fifth Avenue, New York, NY, 10118, US

(21) Appl. No.: 10/805,527

(22) Filed: Mar. 22, 2004

Related U.S. Application Data
(62) Division of application No. 10/307,510, filed on Dec. 2, 2002, now abandoned.

(30) Foreign Application Priority Data
Jun. 23, 2002 (IL) 150364
Jul. 3, 2002 (IL) 150577
Jul. 24, 2002 (IL) 150940

(51) Int. Cl. B05D 3/04; B32B 9/04

(52) U.S. Cl. 428/425.8; 427/443.1; 428/446; 428/450

(57) ABSTRACT

An article of manufacture produced by a method for electroless plating a metallic layer on the surface of a non-metallic substrate. The method comprises (a) exposing the non-metallic substrate to a solution comprising non-precious metal ions so as to obtain a non-metallic substrate covered with a layer of non-precious metal ions; and (b) exposing the covered non-metallic substrate obtained in step (a) to a reducing solution comprising a reducing agent capable of reducing the metal ions that cover the substrate from their oxidation state in step (a) to a lower oxidation state, preferably to zero valence state. In a preferred embodiment, metallization is accomplished by inducing precipitation of metal, e.g. copper, on the surface to be metallized (this effect also being referred to as “plate-out”), via decomposition of the electroless solution. The inventive process contrasts with the prior art, wherein electroless copper deposition is predominantly initiated or triggered through a Pc-bearing layer. Preferably, the non-precious metal ions used in step (a) are copper or nickel ions, whereas the plated metal is copper. The non-metallic substrate is made of insulating materials, for example organic polymers, silicon-containing materials, glass-epoxy composites and the like. The reducing agent is selected from a group consisting of borane compounds, e.g. dimethylamino borane (DMAB) and alkali metal or alkaline earth metal borohydrides.

### CROSS-REFERENCE TO RELATED APPLICATIONS

The present application is a divisional application of U.S. patent application Ser. No. 10/307,510, filed Dec. 2, 2002.

### FIELD OF THE INVENTION

The present invention relates to new metallization method designed to electrolessly deposit a metal layer on electrically insulating substrates, without precious metal-based sensitization. The invention is of special benefit for metallization in the manufacture of ULSI devices.

### BACKGROUND OF THE INVENTION

Electroless plating (or metallization) processes and compositions are widely used in a host of industries, and usually involve electroless copper. They have become especially prominent in the fabrication of electronic interconnect devices (ICs), through-hole plated printed circuit boards (PCBs), flat panel displays, and others. For electroless plating of copper to take place on a dielectric substrate, whether a silica wafer or a glass epoxy laminate, the surface to be plated necessitates seeding or sensitization. Two types of seeding methods are prevalent:

1. Vapor deposited copper. This can be followed by electroless or electrolytic deposition of copper, an approach often practiced in the manufacture of ICs.

2. Pd-type seeding in preparation for electroless metal deposition. This practice predominates, in particular for PCBs.

U.S. Pat. No. 6,225,221 to Ho et al., U.S. Pat. No. 6,180,523 B1 to Lee et al, U.S. Pat. No. 6,362,090 to Paik et al., U.S. Pat. No. 3,663,242 to Gulla et al., and EP 1196016 to Itabashi are referenced as indicative of prior art practice.

These types of seeding methods have not been found satisfactory due to inherent problems. Some of the shortcomings are:

1. Inadequate adhesion of the electroless layer to the substrate surface.

2. High cost due to volatile, often prohibitive, Pd prices.

3. Poor stability of the electroless solutions that follow precious metal type seeding, due to “drag-in” contamination of the electroless solution.

4. Inadequate selectivity of electroless plating due to excessive seeding, especially when using Pd.

5. Reduced electrical conductivity of the Cu layer due to inclusion of Pd in the deposit.

6. Often inadequate reproducibility of vapor deposited seeding.

7. Curtailed throughput of vapor deposition processes.

8. The need for powerful barrier layers to avoid or minimize copper migration.

9. Potentially excessive electromigration.

Broadly speaking, electroless copper plating methods and compositions are generally designed to fulfill two types of objectives:

1. Achieve a minimal metallic layer that will enable subsequent electroplating or additional electroless plating to the desired final thickness of the copper. Usually, copper thicknesses in the range of 0.01 to 1.0 micron or less, will suffice to satisfy this need.

2. Attain desired final, total copper thickness via electroless copper, when choosing to forgo electroplating.

The chemistries and process conditions of electroless copper baths will generally depend on which of these objectives is to be achieved. Indeed, objective #1 is thought to be best served by formulating a strongly stabilized composition, operated at ambient temperature, predominantly in the range of 20-30° C., in order to achieve adequate long-term solution operability, also referred to as solution “life”. The mechanical characteristics of deposits in category #1 above, such as ductility, strength, co-deposited impurities, ability to withstand solder shock, etc. are secondary, because the quality of the final conductor lines, filled vias or interconnections, will be overwhelmingly dictated by the second layer plated electrolytically or electrolessly. Indeed, the thickness-building composition is chosen principally for desired metallurgical or electrical features.

In contrast to the secondary importance of the mechanical properties of deposits in category # 1 above, mechanical requirements of the Cu layer in category # 2 above, are crucial. Thus, electroless copper compositions serving objective # 2 will generally be highly stabilized and will contain ductility-promoting additives, affording plating at high temperature i.e. 70° C. or higher, that are perceived to enhance both plating rate and most importantly, improve metallurgical structures of the copper layer. However, these conditions are not conducive to long solution life.

The prior art often undertakes to achieve both above objectives #1 and #2 with a single electroless copper composition and process, a difficult task with an overly stringent process window.

Similarly, the prolonged and abundant efforts by the prior art to obviate the need for Pd sensitization in electroless plating, as reflected in numerous patents, have yet to produce industrially accepted, production-worthy technology. U.S. Pat. Nos. 4,131,699 and 5,009,965 to Feldstein, as well as patents granted to others, exemplify a host of Pd-replacing disclosures that failed to materialize in the industry. It is of interest to note that most, if not all prior art attempts to replace Pd, rely on colloidal compositions of non-precious metals, presumably simulating the very successful tin/palladium colloids of the prior art.

Electroless solutions are known to be thermodynamically unstable, the instability being aggravated by dragged-in Pd. This especially holds for electroless copper solutions that are based on formaldehyde reducers. This instability problem restricted workers to operate electroless baths at ambient temperature (25-30° C.), and to employ relatively high levels of electroless solution stabilizers, whose presence extends useful solution life and minimizes above-mentioned bulk decomposition, and metal plate-out on heaters and the walls or bottom of the container. But, by strongly focusing on solution stabilization via substantial levels of additives such as cyanides, sulfides and a host of others (all of which are powerful catalytic poisons), aggressive Pd-type sensitization became a must, or else metallization was absent or incomplete, leading to rejects.

Electroless copper compositions are autocatalytic. This implies that metal deposition should be theoretically easily and swiftly initiated, triggered over copper surfaces. In reality though, due to aforementioned powerful stabilizers present in most, if not all industrial electroless chemistries, it will not plate appreciably over uncatalyzed solid copper metal, e.g. copper cladding of printed circuit laminates. In a way, copper stabilizers render the bath essentially non-autocatalytic to copper metal.

Thus, it would be desirable to provide a method for electroless plating without precious metal sensitization which would preclude the need for Pd sensitization in electroless plating or for seeding by vapor deposited metals and that would not rely predominantly on colloidal compositions.

### SUMMARY OF THE INVENTION

Accordingly, it is a broad object of the present invention to overcome the problems of the prior art and provide a method for electroless plating without precious metal sensitization.

In accordance with a preferred embodiment of the present invention, there is provided a method for electroless plating a metallic layer on the surface of a non-metallic substrate, comprising:

(a) exposing the non-metallic substrate to a solution comprising non-precious metal ions so as to obtain a non-metallic substrate covered with a layer of non-precious metal ions; and

(b) exposing the covered non-metallic substrate obtained in step (a) to a reducing solution comprising a reducing agent capable of reducing the metal ions that cover the substrate from their oxidation state in step (a) to a lower oxidation state, preferably to zero valence state.

In a preferred embodiment of the present invention, metallization is accomplished by inducing metal, e.g. copper, precipitation on the surface to be metallized (this effect also being referred to as “plate-out”), via decomposition of the electroless solution. The process of the invention thus contrasts with the prevailing practice of the prior art, wherein electroless copper deposition is predominantly initiated or triggered through a Pd-bearing layer.

Preferably, the non-precious metal ions used in step (a) are copper or nickel ions, whereas the plated metal is copper. The non-metallic substrate is made of insulating materials, for example organic polymers, silicon-containing materials, glass-epoxy composites and the like. The reducing agent is selected from a group consisting of borane compounds, e.g. dimethylamino borane (DMAB) and alkali metal or alkaline earth metal borohydrides.

According to another aspect, the above method may comprise a further step of contacting said substrate covered with a layer of reduced metal ions as obtained in step (b) with an electroless or electroplating bath.

In another preferred embodiment, the method for electroless plating without precious metal sensitization comprises an additional two steps after the initial exposure of the substrate to the solution comprising non-precious metal ions in step (a). The steps comprise:

(a1) exposing the substrate obtained in step (a) to a solution that imparts insolubility towards a water rinse to the layer of reducible ions covering the substrate; and

(a2) rinsing with water.

This embodiment enables the use of a water rinse between step (a) and step (b). It was found that use of a water rinse directly following step (a) weakens electroless initiation/triggering, perhaps because the water rinse removed a portion of the adsorbed ions, leading to a sparser nucleation layer. However, a water rinse is desirable in order to prevent the potential problem of contamination of the processing solution in step (b), due to drag-in. The addition of step (a1) imparts stability, towards rinsing, to the reducible ions adsorbed onto, or into, the substrate surface, thereby enabling rinsing and subsequent processing without removal of the reducible ions from the surface to any significant degree. Step (a1) can also be visualized as “fixing” above-mentioned ions on the substrate. The solution used in step (a1) will at times be appropriately referred-to hereinafter as “fixer”, for brevity.

A proper fixer may preferably bear at least one of the following properties:

1. Aqueous, as opposed to solvent-based.

2. Alkaline, as opposed to acidic, because the ensuing process steps use alkaline chemistries.

3. Devoid of anions that are catalytic poisons, e.g. sulfides, cyanates, thiocyanates, and the like.

4. Comprise electroless deposition promoters i.e. potential electron donors, for example hydrazine, hypophosphite, and the like.

5. Easily water-rinsable. Rinsability can at times call for inclusion of a surfactant into the fixer composition.

Following exposure to the fixer composition, the substrate can be water-rinsed, at times copiously, without substantially removing adsorbed reducible ions, while minimizing contamination of the ensuing step by drag-in.

In yet another preferred embodiment, the reducing solution in step (b) further contains a metal or metal compound, the metal being selected from groups Ib, VIII and the Lanthanides, wherein the reducing agent is more rapidly capable of reducing the non-precious metal ions that cover the substrate from their oxidation state in step (a) to a lower oxidation state.

According to a further preferred embodiment, the reducing agent is DMAB and the metal or metal compound used in step (b) is copper or a copper compound. The concentration of the metal or metal compound is approximately 0.1 ppm or higher. DMAB is often the reducer of choice for successful practice of the above-cited embodiment. The reaction of the DMAB with the metal or metal compound produces a dark composition which both speeds and completes the reaction and usually produces a black film on the surface.

Indeed, it is hypothesized that the reducible metal ions covering the substrate to be metallized, undergo a reduction reaction in the DMAB solution that potentially reduces to some types of lower oxidation state species, comprising dark-colored black layers/films, presumably metal hydrides, hydride intermediates/derivatives and other active electron-donor entities, in addition to hydrogen. The reduction products obtained in DMAB are intuitively theorized to play a central role in initiating electroless deposition.

The present invention focuses principally on the deposition of the initial metal layer that will enable additional metal deposition, electrolessly or electrolytically, as needed. Electroless baths of this invention are composed and operated in a moderately stable mode, which would not require precious metal activation. Moderately stable means stable enough to avoid the previously mentioned bulk-decomposition of the electroless bath.

The present invention implements copperization without Pd activation, by essentially preserving the thermodynamic autocatalytic nature of electroless copper through minimal use, if any, of stabilizers in the bath, thereby facilitating electroless initiation via surface nuclei other than catalytically aggressive Pd, e.g. over copper-bearing nuclei.

To further promote autocatalysis of electroless copper compositions, while at the same time minimizing the risk of bulk decomposition, one skilled in the art will design a carefully balanced process and electroless copper bath chemistry. This implies proper selection and optimization of copper ion concentration, anions of the copper salt used, type and concentration of chelating agents, electroless solution pH, etc. As a point of illustration, one can reinforce autocatalysis of electroless copper by choosing chelating agents known to yield reasonably, but not overly “tight” copper complexes as reflected by the stability constant of the complex, moderately high pH and reducer content, in addition to elevated plating temperatures.

In opting for moderate (as opposed to “extreme”) long-term stability as a means for “easier”, catalytically less demanding initiation in electroless copper baths, this application contemplates for example, non-restrictively, the use of oxygen as the main, though not necessarily sole, electroless copper stabilizer.

This invention is in fact exploiting the thermodynamic instability of electroless chemistries, in order to bring about induced, though controlled and functionally adequate electroless plate-out i.e. metal deposition at the solid/solution interface, using non-precious metal nucleation. Long-term stability of electroless baths is somewhat sacrificed in favor of easier initiation of metal deposition on the workpiece, thereby obviating the need for Pd.

Additional features and advantages of the invention will become apparent from the following description.

### DETAILED DESCRIPTION OF THE INVENTION

The method of the invention thus focuses on the idea of providing the surface of non-conductive workpieces with non-precious metal nuclei. It also envisions designing electroless compositions and processes enabling electroless deposition to be initiated by less catalytically aggressive, non-precious metal nuclei on the surface of the workpiece to be metallized. Above objective will be generally, though not solely, accomplished by the following steps:

1. The surface of the workpiece to be metallized is prepared for optimum adsorption of reducible metal ions from solution. Such surface preparation may include plasma, fluoride-based compositions (especially for wafers), microemulsions, wetting agents, silane-type adhesion promoters, and others. In addition to insuring cleanliness of the workpiece, this step desirably creates a topography conducive to adequate metal adhesion, as previously mentioned.

2. The surface to be plated is exposed to solutions, preferably aqueous, containing compounds of metal ions to be reduced to metal. Such solution will be conveniently referred to as “nucleator”. The objective of this step is to adsorb the ions to be reduced onto or into the surface to be metallized. Additives, such as surfactants, that can aid adsorption and wetting will at times be desirable for use during this and potentially other steps. Indeed, it is imperative that the surface of the workpiece to be metallized be completely and uniformly covered with a layer of the reducible ion-containing solution.

3. Preferably at times, without water-rinsing and following step #2, the sample is drained from excess solution that adheres to the sample. Of course, in the case of wafers, draining via spinning is an option. In most instances, water rinsing following step # 2 is strongly desirable wherever practicable, without excessive removal of reducible metal ions from the surface to be plated.

Steps 3a and 3b are optionally added:

3a. In a preferred embodiment, the substrate is exposed, after its exposure to the nucleator composition, to a solution that imparts stability towards water-rinse to the reducible ions adsorbed onto, or into the substrate surface, thereby enabling rinsing and subsequent processing without removal of the reducible ions from the surface to any significant degree.

3b. Water-rinse following step 3a.

4. After step 3 or 3b above, the workpiece is exposed to a reducing solution, preferably an aqueous solution comprising a strong reducing agent, capable of reducing the layer of the reducible metal ions that have been adsorbed onto or into the surface to be metallized. Elevated temperature, strong work agitation, as well as other process conditions that will enhance reduction, may be implemented in this step, which is perhaps the dominant one of the invention. Preferred reducers comprise borane-based compounds, particularly amino boranes, borohydrides and the like. Again, optimal execution of step 4 is perceived central to successful practice of the invention. Indeed, it is the film or layer covering the workpiece during this step 4 that serves as initiator of electroless deposition, in lieu of Pd-bearing catalysts of the prior art.

According to a preferred embodiment of the present invention, the reducing solution in step 4 has added to it trace amounts of metal ions, e.g. copper or silver ions. This often causes the DMAB solution to undergo a color change from clear to dark. The solution also displays effervescence, presumably caused by hydrogen evolution. This dark DMAB composition noticeably improves speed of reduction and completeness of reduction, leading to lower oxidation state of the reducible ions on the workpiece as indicated by a black coating that forms on the surface of the workpiece as it is contacted by the DMAB composition.

While not being limited by mechanism or theory, it is suggested that by adding trace amounts of certain metal ions in the reducing solution, these ions have a catalytic effect in triggering and enhancing the reducing functionality of DMAB in general, and in achieving non-precious metal activation that will initiate electroless plating, in particular.

As will be apparent to one skilled in the art, additional suitable metallic ions can be utilized. Ions of metals of groups Ib, VIII and the Lanthanides are examples of suitable candidates.

5. The reducing bath is followed by plating either by electroless plating or electrolytic plating.

It was observed that in all instances, superior metal deposition was obtained when the water rinse was skipped between the DMAB and the electroless plating solution. While the composition of the film that forms on the surface in the DMAB solution is unknown, it is postulated that this may be due to the presence of hydrides and/or hydrogen on the workpiece as it exits the DMAB, and prior to entry in the electroless bath, that further facilitate copper initiation in the electroless bath. Presumably, water rinsing causes the hydrides or hydrogen to be dissipated/lost from the surface. This appears to support the assumption stated previously, that hydrides and/or hydrogen derivatives play an important role in practicing the invention.

The copper hydride mechanism is plausible, as potentially supported further by noting that the DMAB solution develops a black powder with continued use. This implies the need for continuous filtration to remove solids that cause idle, wasteful DMAB decomposition on standing, which is indicated by copious effervescence, even without the presence in solution of a workpiece to be plated. The detailed mechanism of electroless metal reduction, whether on the surface of a workpiece or during solution bulk decomposition, is understood to undergo a complex chain of intermediate stages, culminating with copious hydrogen evolution. This further supports the non-limiting theory that formation of hydrides, e.g. copper hydride, hydride derivatives such as active hydrogen, and possibly others, on the surface to be metallized may play an eminent role in reduction to practice and understanding of the invention, i.e. metallization without precious metal catalysis, as indicated in the examples described previously.

It is further surmised, that the products obtained on the surface following immersion in the DMAB solution may include in addition to hydrides, copper metal, cuprous or cupric oxides, or mixtures thereof, as well as other copper derivatives.

Electroless plating, e.g. electroless plating of copper, is achieved in the method of the present invention by inducing metal reduction via electroless solution “plate-out”, on the surface to be metallized. The invention thus contrasts with the prevailing practice of the prior art, wherein electroless copper deposition is predominantly initiated or triggered through a Pd-bearing layer, which is a very potent but often overly-aggressive catalyst.

The term “plate-out” is customarily referred to in the industry negatively and relates to undesirable, often unexpected, random metal deposition on the walls and bottom of the vessel or on the heating element in contact with the electroless solution. Contrarily, the term “plate-out” referred-to in the present invention, is introduced solely for illustrative purposes, without limiting the invention. It refers to electroless plating compositions and processes that are conducive to easy triggering or initiation of deposition over non-precious metal nuclei. The hypothetical parallelism between “plate-out” and the invention is proposed solely in an effort to help visualize and possibly exemplify metallization without using Pd, or vapor phase sensitization. Also, the proposed “plate-out” concept may assist workers skilled in the art in the optimal practice of the invention, possibly prompting them to devise additional approaches within the spirit of this disclosure.

The method of the invention stimulates and purposely brings about plate-out, by creating conditions enabling electroless metal deposition on metal-bearing nuclei, other than precious metal. The proposed mechanism of induced metal precipitation via initiated plate-out, or stimulated solution “decomposition” at the substrate/electroless solution interface, is a new domain in electroless deposition. Hence the following options are offered to enhance the process of the invention:

1. The workpiece to be electrolessly plated can contact the electroless solution with an elevated surface temperature that will help trigger and/or speed up copper metal deposition. This is an especially attractive method for wafers, where elevated process temperatures are common, and where processing can be achieved via wafer spinning, as opposed to immersion. Wafer processing via spinning is a well-entrenched, often preferred IC fabrication process. Also, in the case of wafers one can envision a variety of means to deliver thermal energy to the entire surface to be metallized, or perhaps more appealingly, to selective areas thereof, e.g. via thermal lasers.

Also, in metallizing wafers it is possible to dispense on the wafer a limited, small and controlled amount of processing solution, e.g. electroless solution, which can be heated to high temperatures via the wafer in order to hasten metal deposition on the surface of the wafer that is to be metallized. Such a method can be especially advantageous for speeding up electroless copper plating rates during filling of trenches, vias, and the like. In essence, one can envision the surface of the wafer serving as a “virtual”, makeshift container for the processing solution in many or all manufacturing steps, particularly in the electroless copper bath.

This method potentially has the makings of offering unique opportunities and possibilities in metallizing wafers, flat panel displays, and the like. Such an approach is somewhat analogous to puddle development (as opposed to development by immersion or spray) of micro photoresists, a familiar method in the industry. The aforementioned method will result in solution economy, in addition to enhanced rate of deposition, because it minimizes the importance of using large volumes of electroless copper working solutions. In such instances, long term electroless bath stability is of secondary importance, as one can store two separate, indefinitely stable formulation components and dispense them in the desired ratios, and desired volumes, onto the surface to be metallized where they will mix and become operative.

2. The surface to be plated can be engineered to promote high surface energy, believed to be the basic driving force favoring surface impregnation or adsorption, e.g. adsorption of metal ions reducible to metal, as disclosed in the invention. It is a generally accepted theory that high surface energy promoting adsorption and adhesion to substrates is occasioned by Van-der-Waals bonds.

The literature abounds with compositions and methods designed to achieve high energy surface topographies that maximize strongly bonded adsorption, also a prerequisite for optimum adhesion of the electroless layer to plated substrates. Such methods and compositions are usually tailored to accommodate the nature of the workpiece receiving the electroless metal layer. For example, plated plastics usually involve exposure to chromic-sulfuric mixtures or plasma, through-hole plated printed circuits use hot aqueous permanganate solutions, silica wafers generally favor treatment with fluoride-bearing formulations and/or plasma, copper metal is surface-etched in aqueous persulfate or peroxide-bearing compositions, and so on.

3. Utilization of electroless plating solution temperatures significantly over ambient, thereby assisting in the triggering of metal precipitation on the surface to be metallized. In doing so, especially where one deals with plating of the work-piece by immersion, which often necessitates large solution volumes, caution must be exercised to avoid causing bulk decomposition of the bath by over-heating. Bulk decomposition is a result of internal, solution nucleation that causes unwanted copper powder drop-out on the bottom and walls of the container, a nefarious and poorly understood, often random occurrence.

4. Entry of the workpiece to be plated in a given process step with a liquid layer that induces metal deposition, e.g. a suitable reducing agent, to reduce metal ions, e.g. copper ions, to metal, e.g. copper.

### EXAMPLES

In all the following examples, DI water was used as the diluent or for make up of solutions. Also, the asterisk (*) denotes a product offered by MacDermid Israel Ltd, under exclusive license by MacDermid Inc., Waterbury Conn. These products were used according to supplier's instructions.

The invention will be illustrated via the non-limiting Examples listed below:

### Example 1

A 3″×3 glass cloth/fabric, the type of which is used in the manufacture of printed circuit board (PCB) panels, was metallized as follows:

1. Immerse in Macudizer (*), a permanganate-based composition routinely used in the manufacture of PCB through hole interconnects, 1 min. ambient temperature.

2. Rinse.

3. Immerse for 5 min., at ambient temperature, in the following aqueous nucleator composition:

5 g/l CuCl₂

10 g/l SnCl₂

40 g/l NH₄Cl

After dissolution in water was complete, above composition was heated with stirring to about 70° C. and allowed to cool to ambient temperature, overnight. The supernatant liquid was decanted to separate it from the copious precipitate that settled on the bottom of the beaker and discarded, yielding nucleator ready for use.

4. Rinse.

5. Drain.

6. Immerse, 10 min., 60 deg C., in aqueous solution of about 10 g/l DMAB.

7. Drain.

8. Immerse in working solution of Macudep 22 (*) for 20 min. at 40° C.

9. Rinse

10. Dry.

Notes:

a. “Sample” denotes the workpiece processed in all Examples.

b. The sample was vigorously hand-agitated in all above steps, especially in #3, #6, and #8.

c. Rinsing was with DI water and, unless specified differently, may have involved several rinsing stations/steps with various durations, as deemed adequate in industrial practice for “efficient/thorough” rinsing action.

c. “Drain”, denotes allowing the sample to essentially air-dry without rinsing it, usually requiring 30 sec to 2 min.

d. The Macudep (*) working solution was allowed to stand overnight at ambient temperature, before use, resulting in easier initiation of electroless deposition.

Observations:

a. Immersion, agitation of the sample in step #6 was accompanied by copious gassing, especially at the sample/solution interface. It emerged with a dark film.

b. Following step #9, the sample was covered with a continuous copper layer, estimated to be approximately 0.1 micron thick, or more.

### Example 2

Same as Example 1, except that the sample was rinsed for 15 sec. following step #6. Onset of copper deposition following immersion in Macudep 22 (*) working solution, was not as immediate and less vigorous as compared to Example 1. Otherwise the copper film following step #10 was essentially similar by visual observation as compared to Example #1.

### Example 3

Same as Example 1, except that the sample consisted of 3″×3″ glass epoxy copper-clad laminate from which the copper has been etched away. The copper layer following step #10 was essentially identical to Example 1.

### Example 4

Same as Example 2, except using a sample as in Example 3. Same observations apply as mentioned in connection with Example 2.

### Example 5

Same as Example 1, except that the sample consisted of copper-clad glass epoxy laminate with interconnect holes to be copperized. Also, in step #1, Macudizer (*) was at 70 deg. C, and immersion time was 5 min.

Following step #10, copper coverage in the holes was deemed adequate, i.e. complete and void-free.

### Example 6

Same as Example 1, the nucleator being spent Continuetch (*), an aqueous cupric ammoniacal solution. Results were the same as in Example 1.

### Example 7

Same as Example 2, except that the nucleator used was the same as in Example 7. Results were the same as Example 2.

### Example 8

A 3″×3″ glass cloth (fabric) that is used in manufacture of PCB glass epoxy pre-pregs was copperized as follows:

a. Immerse in Macudep 22 (*) working solution, a formaldehyde-based electroless copper for 5 min. at 40° C.

b. Drain sample from excess Macudep 22 solution.

c. Immerse in 10 g/l aq. DMAB solution, 5 min, 60 deg C., with vigorous work agitation. Copious gassing was observed in the vicinity of the immersed sample, which developed a dark, blackish layer.

d. Brief water rinse, 5-10 sec., R.T.

e. Immerse in Macudep 22 (*) working solution, 10 min., 40° C., with vigorous work agitation of the sample. After rinsing and drying, the sample was copperized, i.e. covered with a continuous copper layer.

In this Example, Macudep 22 (*) serves as both nucleator and electroless bath.

### Example 9

Same as Example 8, except that the sample received a 10 sec. water rinse after step b, and before step c. The copper layer obtained after step e, was judged thinner by observation as compared to example 1.

### Example 10

Same as Example 8, except that the glass fabric was replaced with a 3″×3″ panel of a copper-clad glass epoxy, FR-4 laminate from which the copper has been etched away. Following water rinse and dry, the panel was completely copperized, though the copper layer was judged thinner than in Example #1, perhaps as a result of stronger surface adsorptivity of the glass fabric than the surface of FR-4.

In examples 11-16, dimethylamino borane (DMAB) was freshly prepared for each example, thus eliminating the effect of a “broken-in” DMAB composition. “Broken-in” implies a DMAB composition that shows gassing. The sample (the substrate processed in a given example) emerged from the DMAB solution with a dark, often intensely black color.

### Example 11

A 3″×3″ glass cloth (fabric), same as used to prepare “prepreg” in the manufacture of glass-epoxy laminates, was processed as follows:

1. Immerse in Macudizer (*), 5 min., approximately 70 deg. C.

2. Rinse thoroughly with water until the sample is essentially colorless, i.e. no longer displaying typical permanganate color.

3. Immerse in spent Continuetch (*), (an ammoniacal aq. cupric solution) at ambient temp., for 5 min. The sample emerged with an intensely blue color, typical of ammoniacal cupric complex.

4. Immerse in 50 g/l aq. trisodium phosphate, 5 min., 50-60 deg. C.

5. Rinse.

6. Immerse in DMAB, 10 g./l, 60 deg. C.

7. Immerse, without rinsing after step #6, in Macudep 22 (*), 20 min., 35 deg.C.

8. After rinsing and drying, the sample was completely covered with a copper layer, estimated as being at least 0.1 micron thick.

### Example 12

Same as Example 11, except that the glass cloth sample was replaced with 3″×3″ glass-epoxy laminate from which the copper has been etched away. Results were essentially the same as in Example #1.

### Example 13

Same as Example 11, except that the sample was thoroughly rinsed in water following step #6 (DMAB). Initiation of electroless copper deposition was sluggish, and the copper layer was deemed thinner compared to Example 1.

### Example 14

Same as Example 13, except that the sample was glass-epoxy. Results were similar to Example 13.

### Example 15

Same as Example 14, except that a different nucleator was prepared and used as follows:

CuCl₂ . . . 15 g/l

SnCl₂ . . . 7.5 g/l

NH₄Cl . . . 25 g/l

After dissolving above ingredients in DI water, the mixture was heated to about 70 deg. C, and solids were allowed to settle. The supernatant was used as nucleator, and the sample was immersed therein for 5 min., with vigorous hand-agitation. Metallization results were the same as in Example 11.

### Example 16

Same as Example 15, except that the sample consisted of copper-clad glass-epoxy, with interconnecting through-holes. Following Macudizer(*), it was immersed in 100 g/l ammonium persulfate solution for 5 min., 40 deg. C.

Copper coverage in the holes was complete, and Cu—Cu adhesion was good.

While the invention has been described and exemplified using nucleator comprised of copper ions, and via electroless plating of copper, it is understood that encompasses other nucleators, e.g. comprising nickel ions, and other electroless plating baths, e.g. nickel. Also, even though the fixer solution used in the examples above, were based on trisodium phosphate, other fixers may be used, for example heavy metal ion precipitating compounds, such as carbonates, borates, silicates, hypophosphates, caustic, caustic comprising hypophosphites, and the like. In choosing a fixer, one can be guided by the solubility constant of the reducible ion with a given fixer compound.

In examples 17-26, vigorous back/forth agitation was imparted to the samples in all process steps. Its importance for successfully practicing the invention cannot be overemphasized.

### Example 17

A 3″×3″ copper-clad epoxy panel with interconnecting through-holes was processed as follows:

1. Immerse in Macudizer (*), a permanganate aq. solution.

2. Rinse with water.

3. Immerse in 9279 Reducer (*) aq. solution.

4. Rinse with water.

5. Immerse in aq. solution of G-3 (*), a persulfate-based compound that promotes good Cu/Cu adhesion.

6. Rinse with water.

7. Immerse, 5 ml., ambient temp., in a nucleator solution containing:

5 g/l CuCl₂

10 g/l SnCl₂

40 g/l NH₄Cl

8. Immerse in aq. triphosphate solution, 50 g/l, 50 deg. C., 5 min.

9. Rinse with water.

10. Immerse 5 min. in aq. DMAB solution, 10 g/l, 60 deg. C.

Note: prior to contacting the sample to be plated, 1 drop of spent Continuetch (*), a cupric copper-bearing alkaline solution, was added to the DMAB with vigorous agitation. The solution turned black, accompanied by copious gassing.

11. Immerse in Macudep 22 (*) electroless copper, 35 deg. C., 20 min.

12. Rinse with water.

13. Dry.

Copper coverage in the holes was complete, with no visible voids (unplated areas), as indicated by satisfactory through-hole electrical conductivity. Copper-copper adhesion was satisfactory.

### Example 18

Same as Example 17, except that the DMAB solution was clear and showed no gassing, since no Continuetch(*) had been added, as in EXAMPLE 17. Copper coverage in the holes was incomplete, as indicated by lack of through-hole electrical conductivity.

### Example 19

Same as Example 17, except that nucleator composition in step # 7 was as follows:

SnCl₂—5 g/l

CuCl₂—15 g/l

NH₄Cl—50 g/l

The method of preparing the above composition was same as disclosed above. Results were the same as in Example 17.

### Example 20

Same as Example 17, except that the nucleator solution was spent Continuetch (*).

The results were the same as in Example 17. It was observed that the sample to be plated blackened considerably faster in the DMAB solution, implying superior reduction kinetics with reducible ions originating in nucleator of Example 20.

### Example 21

Same as Example 17, except that the DMAB solution was 5 g/l.

Results were the same as in Example 17.

### Example 22

Same as Example 17, except that the DMAB solution was operated at 40-45 deg. C. Results were the same as in Example 17, though blackening of the sample took longer vs. DMAB at 60 deg.C.

### Example 23

Same as Example 17, except that a small amount (estimated at less than 0.1-0.2 g) of the black solid that settled overnight in the DMAB of Example 17 was added. This was instead of the drop of spent Continuetch (*) in Example 17. After stirring vigorously, the DMAB solution developed internal gassing and turned slightly darker, projecting increased reduction activity.

### Example 24

Same as Example 17, except that about 10 drops of ammoniacal NiCl₂ (about 5 g/l of Ni⁺⁺) replaced the addition of Continuetch (*) to the DMAB. No internal gassing and no solution darkening were evident.

### Example 25

Same as Example 17, except that 1 drop of 1 N aq. solution of AgNO₃ replaced the Continuetch (*) addition.

Following stirring, the solution darkened and gassing was more immediate than in Example 17, implying increased catalytic activity of Ag⁺ vs. Cu⁺⁺.

### Example 26

Three solutions were prepared with varying concentrations of DMAB, all heated to about 60 deg.C, and observed for darkening as a function of number of drops of Continuetch (*) added.

Results:

10 drops of a 0.6 g/l DMAB solution—no blackening of solution was observed after 5 min. and no gassing. A bluish precipitate, presumed to be cupric hydroxide, settled on the bottom of the beaker.

2 drops of a 1.2 g/l DMAB solution—blackening occurred after 2 min., accompanied by gassing.

1 drop of a 3.0 g/l DMAB solution—blackening was instantaneous, accompanied by vigorous gassing.

It is postulated that blackened solutions resulting from adding, for example, drops of spent Continuetch (*) to the DMAB compositions (as opposed to clear DMAB solutions) are indicators of superior functionality, made possible by the invention. This, coupled with the findings of Example 21, demonstrate operability of reduced DMAB concentration, again as a result of the teachings of the invention. Reduced DMAB concentration is a desirable and cost-effective contribution of the invention.

Example 22 further shows, that the teaching of the invention enables lower DMAB process-temperatures. This too, is a functional and cost-saving advantage.

While the invention was described in terms of DMAB as the reducer of choice, the concept (reinforcing reduction capability, as indicated by hydrogen evolution, via addition of trace amounts of metal ions) is applicable to other reducers thermodynamically able to reduce metal ions covering the workpiece as it emerges the nucleator composition.

It was noted that initiation of copper deposition on the glass cloth/fabric was generally faster as compared with glass epoxy. It is surmised that it is caused by stronger surface adsorptivity of the glass fiber, either because of topography and/or proprietary treatment provided by the supplier.

Having described the invention with regard to certain specific embodiments thereof, it is to be understood that the description is not meant as a limitation, since further modifications will now suggest themselves to those skilled in the art, and it is intended to cover such modifications as fall within the scope of the appended claims.

I claim:

1. An article of manufacture produced by a method for electroless plating a metallic layer on the surface of a non-metallic substrate, said method comprising:
(a) exposing the non-metallic substrate to a solution comprising non-precious metal ions so as to obtain a non-metallic substrate covered with a layer of non-precious metal ions; and
(b) exposing said covered non-metallic substrate obtained in step (a) to a reducing solution comprising a reducing agent for reducing the metal ions that cover the substrate from their oxidation state in step (a) to a lower oxidation state, preferably to zero valence state.

2. The article of manufacture of claim 1, said article being selected from the group of: ULSI device, PCB, IC and LCD.

3. The article of manufacture of claim 1, wherein said method further comprises, after step (a) and before step (b), the steps of:
(a1) exposing said covered non-metallic substrate obtained in step (a) to a solution that imparts water insolubility to said layer of non-precious metal ions covering the substrate; and
(a2) rinsing with water.

4. The article of manufacture of claim 1, wherein said reducing solution further comprises at least one of a metal and a metal compound, said metal being selected from the group of: group Ib, group VIII and the Lanthanides.

5. The article of manufacture of claim 1, wherein said non-precious metal ions in step (a) comprises copper ions.

6. The article of manufacture of claim 1, wherein the non-metallic substrate comprises organic polymers and a silicon comprising material.

7. The article of manufacture of claim 1, wherein said reducing agent is a borane reducing agent.

8. The article of manufacture of claim 1, wherein said reducing agent is dimethylamino borane (DMAB).

9. The article of manufacture of claim 4, wherein said at least one of a metal and a metal compound used in said reducing solution is selected from the group of: silver, a silver compound, copper and a copper compound.

10. The article of manufacture of claim 4 wherein said reducing solution reacts with said at least one of a metal and a metal compound to produce a metal hydride.

11. The article of manufacture of claim 1 wherein said method further comprises the step of:
(c) contacting the covered substrate obtained in step (b) with an electroless copper plating bath.

12. The article of manufacture of claim 1 wherein said method further comprises the step of:
(c) electroplating the covered substrate obtained in step (b) with copper.

13. An article of manufacture produced by a method for electroless plating a metallic layer on the surface of a non-metallic substrate, comprising:
(a) exposing the non-metallic substrate to a solution comprising non-precious metal ions so as to obtain a non-metallic substrate covered with a layer of non-precious metal ions;
(b) exposing said covered non-metallic substrate obtained in step (a) to a solution that imparts water-rinse insolubility to said layer of non-precious metal ions covering the substrate;
(c) rinsing with water; and
(d) exposing said covered non-metallic substrate obtained in step (c) to a reducing solution comprising a reducing agent for reducing the metal ions that cover the substrate from their oxidation state in step (c) to a lower oxidation state, preferably to zero valence state.

14. An article of manufacture produced by a method for electroless plating a metallic layer on the surface of a non-metallic substrate, comprising:
(a) exposing the non-metallic substrate to a solution comprising non-precious metal ions so as to obtain a non-metallic substrate covered with a layer of non-precious metal ions; and
(b) exposing said covered non-metallic substrate obtained in step (a) to a reducing solution comprising:
a reducing agent for reducing the metal ions that cover said substrate from their oxidation state in step (a) to a lower oxidation state, preferably to zero valence state; and
at least one of a metal and a metal compound, said metal being selected from the group of: group Ib, group VIII and the Lanthanides.

15. An article of manufacture produced by a method for electroless plating a metallic layer on the surface of a non-metallic substrate, comprising:
(a) exposing the non-metallic substrate to a solution comprising non-precious metal ions so as to obtain a non-metallic substrate covered with a layer of non-precious metal ions;
(b) exposing said covered non-metallic substrate obtained in step (a) to a solution that imparts water-rinse insolubility to said layer of non-precious metal ions covering the substrate;
(c) rinsing with water; and
(d) exposing said covered non-metallic substrate obtained in step (c) to a reducing solution comprising:
a reducing agent for reducing the metal ions that cover the substrate from their oxidation state in step (c) to a lower oxidation state, preferably to zero valence state; and
at least one of a metal and a metal compound, said metal being selected from the group of: group Ib, group VIII and the Lanthanides.

16. A workpiece comprising a nonmetallic substrate covered with a layer of copper hydride according to the method of claim 1.

17. A workpiece comprising a nonmetallic substrate having a surface covered with a black film according to the method of claim 1.

18. A composition comprising a reducing agent and at least one of a metal and a metal compound, said metal being selected from the group of: group Ib, group VIII and the Lanthanides.

19. A composition according to claim 18 for use in a method for plating a metallic layer on the surface of a non-metallic substrate.
